(19) United States
(12) Patent Application Publication
(10) Pub. No.: US 2012/0043962 A1
(43) Pub. Date: Feb. 23, 2012

(54) METHOD AND APPARATUS FOR EDDY CURRENT INSPECTION OF CASE-HARDENDED METAL COMPONENTS

(76) Inventors: Changting WANG, Niskayuna, NY (US); Haiyan Sun, Niskayuna, NY (US); Anthony Giammarise, Erie, PA (US); Thomas Batzinger, Burnt Hills, NY (US); Mandar Godbole, Bangalore (IN); Nilesh Tralshawala, Rexford, NY (US); Aparna Sheila-Vadde, Bangalore (IN); Michael Sirak, Erie, PA (US); Shubin Liu, Erie, PA (US)

(21) Appl. No.: 12/860,353

(22) Filed: Aug. 20, 2010

(51) Int. Cl. G01R 33/12

(52) U.S. Cl. 324/239

(57) ABSTRACT

A method for determining a case depth of a hardened layer in a surface of a metal object includes: (a) placing an eddy current probe at a location adjacent the surface; (b) using the eddy current probe, generating a time-varying eddy current in the object; (c) using the eddy current probe, outputting a measured eddy current and providing a signal representative of the measured eddy current to a computer; (d) using the computer, comparing the time-varying measured eddy current to a correlation of measured eddy currents to known case depths; and (e) determining the case depth at the location of the probe based on the correlation.

### BACKGROUND OF THE INVENTION

Embodiments of the present invention relate to the inspection of components using eddy current technology and, more particularly, to apparatus and methods for inspecting components having a complex geometric shape.

Metal components, and particularly steel components such as gears, shafts, mechanical joints, and the like, are often heat treated to produce a hardened layer penetrating some small depth into the surface of the component to improve strength and resistance to wear. This is commonly referred to as “case-hardening.” Measuring the case-hardened depth profile is important for quality control to prevent part wear and breakage.

One known quality control method involves sectioning sample components and performing micro-hardness mapping in order to validate the case-hardening process. This process is time consuming and costly, and components can still have undetected defects.

Another quality control method involves using eddy current inspection. It is usually used to detect discontinuities or flaws on the surface of a component. Eddy currents are induced within the component under inspection by alternating magnetic fields created in a drive coil of a probe placed in close proximity to the component. Changes in the flow of eddy currents are caused by the presence of a discontinuity or a crack in the test specimen. The altered eddy currents produce a secondary magnetic field which is received by a sense coil in the eddy current probe which in turn converts the altered secondary magnetic field to an electrical signal which may be recorded for analysis.

There are also commercial instruments available to measure the case depth of cylinders or similar shapes using eddy current coils which encircle the test specimen. However, such instruments can only determine the average case depth of the whole part or only an average along a circumferential direction. Such equipment cannot determine local case depth values. Further, if the test objects are of complex shape and cannot be encircled by the probe, they cannot be measured using these commercial probes.

### BRIEF SUMMARY OF THE INVENTION

These and other drawbacks of the prior art are addressed by the present invention, embodiments of which provide a non-destructive method to measure the local case depth of surface-hardened steel components using eddy current techniques. “Case depth” refers to the depth of a hardened surface layer of a component comprising the hardened surface layer on top of a less-hard (e.g., unhardened) layer.

An embodiment of the invention relates to a method for determining a case depth of a hardened layer on a surface of a metal object. The method includes placing an eddy current probe in a selected location on the surface. The eddy current probe is used to generate a time-varying eddy current in the object. Using the eddy current probe, the time-varying eddy current is measured, and a signal representative of the measured time-varying eddy current is provided to a computer. Using the computer, the measured time-varying eddy current is compared to a correlation of measured eddy currents to known case depths. The method further includes determining the case depth at the location of the probe based on the correlation.

According to another aspect of the invention, an apparatus for determining a case depth at a location on a surface of a metal object includes an eddy current probe, a computer, and signal processing equipment. The eddy current probe includes at least one drive coil and at least one sense coil. The signal processing equipment is operably connected to the computer and the eddy current probe. The signal processing equipment is operable to drive the at least one drive coil in response to the computer and to generate output signals representative of measured eddy currents produced by the at least one sense coil. The computer is programmed to: (i) command the signal processing equipment to generate a time-varying eddy current in the metal object using the at least one drive coil; (ii) receive signals representative of a measured time-varying eddy current from the signal processing equipment; (iii) compare the measured time-varying eddy current to a correlation of measured eddy currents to known case depths; and (iv) determine the case depth at the location of the probe based on the correlation.

According to yet another aspect of the invention, an apparatus is provided for determining a case depth at a location in a surface of a metal object having a shape which comprises a plurality of teeth, each tooth having a land adjoined by spaced-apart flanks, wherein the flanks define recessed roots between adjacent lands. The apparatus includes a first housing, an eddy current probe, and a spring element. The first housing includes a body with at least one foot protruding there from. The at least one foot is configured to engage the flanks so as to retain the first housing in a stable orientation relative to the metal object. The eddy current probe is carried by the first housing, and comprises: a probe housing enclosing at least one drive coil and at least one sense coil, and electrical cabling connected to the drive and sense coils. The spring element is disposed between the first housing and the eddy current probe and arranged to urge the eddy current probe away from the first housing.

### BRIEF DESCRIPTION OF THE DRAWINGS

The subject matter that is regarded as the invention is particularly pointed out and distinctly claimed in the concluding part of the specification. The invention, however, may be best understood by reference to the following description taken in conjunction with the accompanying drawing figures in which:

FIG. 1 is a schematic view of an eddy current inspection system constructed in accordance with an aspect of the present invention;

FIG. 2 is a cross-sectional view of an “air-referenced” eddy current probe;

FIG. 3 is a cross-sectional view of a “standard-referenced” eddy current probe;

FIG. 4 is a cross-sectional view of an “side-by-side-referenced” eddy current probe;

FIG. 5 is a schematic cross-sectional view of an eddy current probe fixture constructed in accordance with an aspect of the present invention;

FIG. 6 is a schematic cross-sectional view of alternative eddy current probe fixture constructed in accordance with an aspect of the present invention;

FIG. 7 is a schematic cross-sectional view of another alternative eddy current probe fixture constructed in accordance with an aspect of the present invention;

FIG. 8 is a schematic cross-sectional view of yet another alternative eddy current probe fixture constructed in accordance with an aspect of the present invention;

FIG. 9 is a block diagram showing an eddy current case depth measurement process; and

FIG. 10 is a schematic view showing a variety of probe shapes positioned adjacent to an exemplary gear.

### DETAILED DESCRIPTION OF THE INVENTION

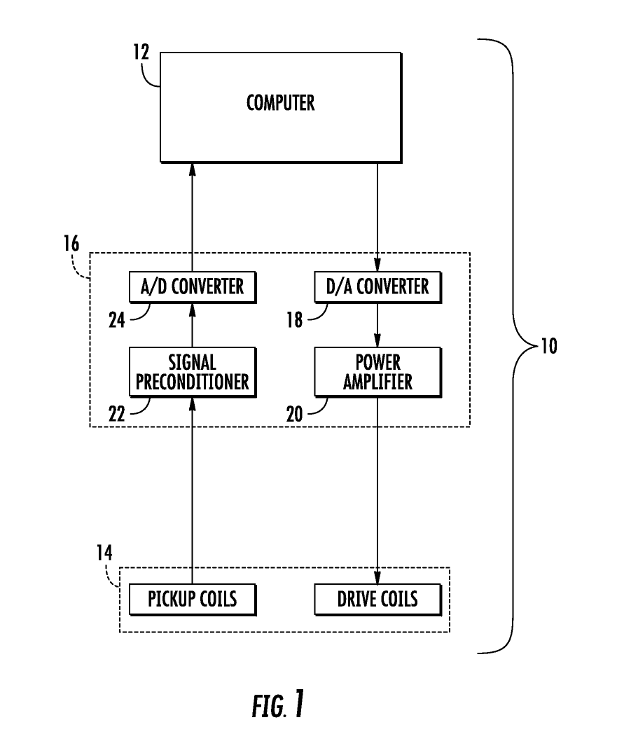

Referring to the drawings wherein identical reference numerals denote the same elements throughout the various views, FIG. 1 illustrates schematically the components of an eddy current inspection system or apparatus 10 suitable for carrying out a method of the present invention for determining a case depth of a hardened layer in a surface of a metal object, according to an embodiment of the invention. The system includes a computer 12, an eddy current probe 14, and signal processing equipment 16 operably interconnected between the computer 12 and the probe 14.

As used herein the term “computer” includes any device capable of executing a programmed instruction set. For example, a conventional microcomputer (sometimes referred to as a personal computer or “PC”) may be used. To provide portability, a “laptop”-type computer may be used. Alternatively, the computer may be a microprocessor or microcontroller-based device that is built in or otherwise integrated with other components. As explained in more detail below, the computer 12 is used for functions such as transfer function computation, case depth calculation, and signal display.

The signal processing equipment 16 may include, for example, a digital-to-analog (D/A) converter 18, a power amplifier 20, signal preconditioner circuit(s) 22, and an analog-to-digital (A/D) converter 24, all of which are depicted functionally, with the understanding that known types of hardware are commercially available to perform each of these discrete functions. The signal processing equipment 16 serves as a substitute for a conventional stand-alone eddy current (“EC”) instrument.

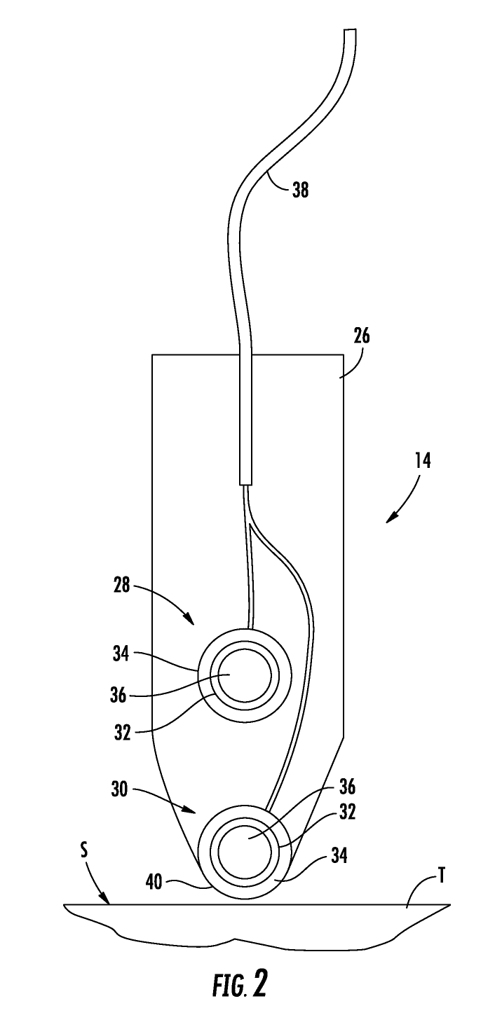

FIG. 2 illustrates the general configuration of an eddy current probe 14, which is suitable for measuring case depth, in particular for curved surfaces, such as gear teeth. The probe is shown disposed on to the surface “S” of a test specimen “T.” As used herein, the term “test specimen” refers generally to any metallic component having a case-hardened surface, which is to be tested for determining case depth, hardness, or otherwise. Examples of particularly suitable test specimens include turbine rotor dovetail slots, gear teeth, and the like. The probe 14 has a probe housing 26 that encloses two sets of reflection coils 28 and 30, connected differentially in a known manner. The size and shape of the probe housing 26 may be varied to suit a particular application. In the illustrated example, each set of reflection coils 28 and 30 includes a generally cylindrical driver coil 32 surrounded by a generally cylindrical pickup coil 34 (also called a “sense” coil). However, the coils could be rectangular or “U”-shaped as well. The sense coil 34 and the driver coil 32 are aligned coaxially. Optionally, a ferrite magnetic core 36 is disposed inside the driver coil 32 to improve the coil sensitivity at low frequencies. A multi-conductor cable 38 provides a connection to the signal processing equipment 16. In use, the coil sets 28 and 30 may be placed in tangential or normal orientations to the surface S.

It is also possible to vary the shape of the eddy current probe depending on the geometry of the components under test. FIG. 10 illustrates several different probe shapes, including representative cylindrical probes 31 positioned both normally (a primary axis of the probe is perpendicular to the component surface) and tangentially (a primary axis of the probe is parallel to the component surface) to a gear “G” having a number of spaced-apart teeth, adjacent to the tooth pitchlines “P” and roots “R,” and two different types of conformally-shaped probes 33 and 35 positioned adjacent to the roots R.

As shown in FIG. 2, the probe 14 is “air-referenced,” meaning one set of the reflection coils 30 is placed at the tip 40 of the probe housing 26 which would be placed in contact with or adjacent to the surface S during testing, while the other reflection coil set 28 is positioned a substantial distance away from the tip 40 (and thus a substantial distance from the surface S). The total output from the probe 14 is the difference between the two sense coils 34. Thus, the induction voltage directly coupled from the driver coils 32 is cancelled when the probe 14 is in ambient air, distant from the test specimen T. With the tip 40 touching the surface S, one set of coils 30 will be on the test specimen T and the other set 28 will be located away from the test specimen T. In this situation the differential voltage output of the two sense coils 34 reflects the test specimen's presence and variation.

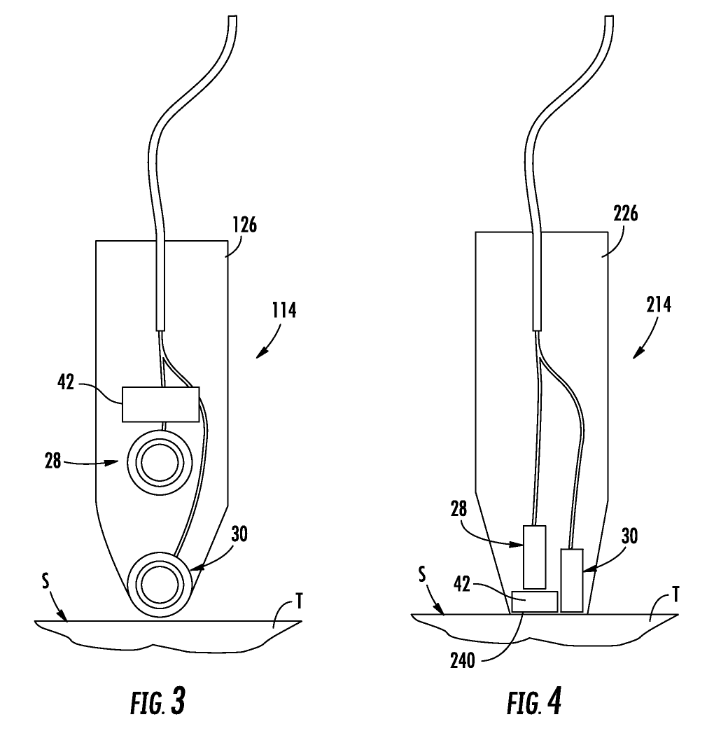

The probe 14 may be referenced in different configurations to suit a particular application. For example, FIG. 3 shows a “standard-referenced” probe 114 similar in construction to the probe 14 with two coil sets 28 and 30, but incorporating a standard 42 of an alloy which is similar to or the same as the test specimen T, but which lacks a hardened surface. The standard 42 is located in the probe housing 126 adjacent to the coil set 28. This type of referencing allows the probe 114 to “see” the difference between a test specimen T and the standard 42. This configuration reduces the common mode signal and allows one to increase the preamplifier gain on the instrument, thus increasing the signal to noise ratio, reducing varying signal components due to temperature change, etc., and increasing sensitivity to the case depth variation than the air-referenced probe 14 described above.

Another embodiment is shown in FIG. 4. A “standard-referenced” probe 214 is similar in construction to the probe 114 with two coil sets 28 and 30, and includes a standard 42. The coil set 30 and the standard 42 are mounted side-by-side near the tip 240 of the probe housing 226. The other coil set 28 is mounted above the standard 42 and next to the coil set 30. The side-by-side coil configuration keeps the coil sets 28 and 30 at similar proximity to the test specimen T. Any heat transfer from the test specimen T to the probe 214 will heat the coil sets 28 and 30 almost identically, which will minimize probe signal drift due to temperature change.

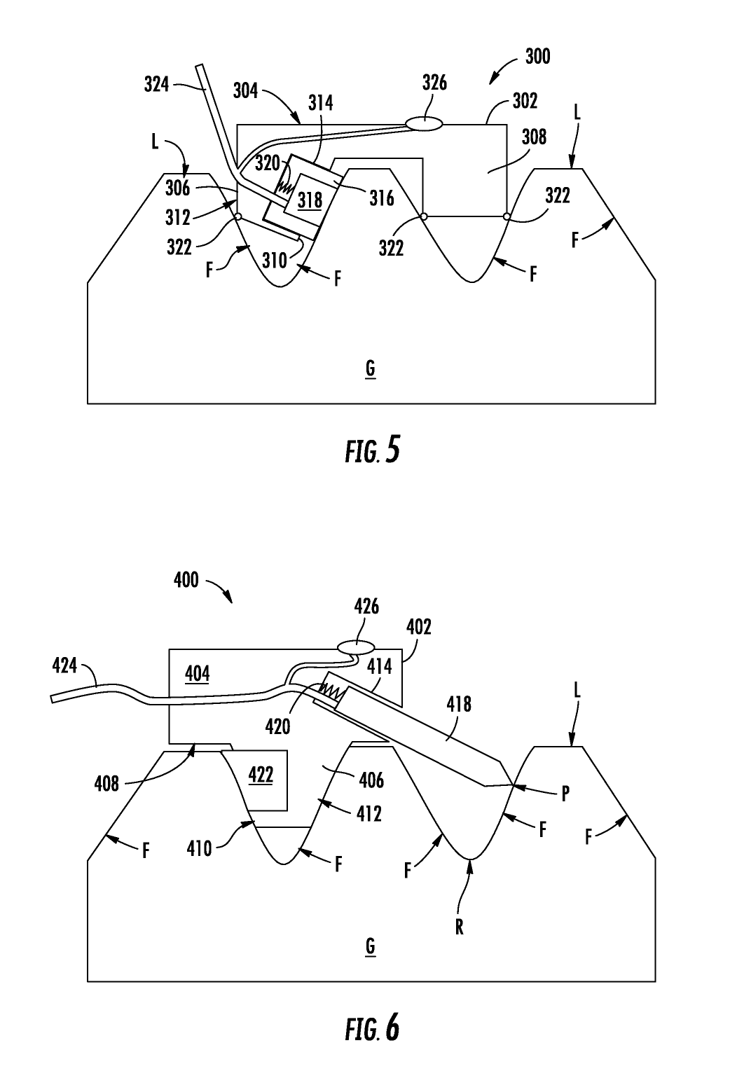

It is particularly desirable to measure the case depth of components such as dovetail slots in turbine rotors, gear teeth in turbine gear sets, and the like. Such components commonly include a surface having alternating peaks (or lands) and valleys (or recesses). For example, FIG. 5 illustrates a portion of a gear G having a number of spaced-apart teeth, each having a top land “L” and flanks “F.” FIGS. 5-9 illustrate some specific fixture configurations that are particularly useful for gear tooth case depth evaluation.

FIG. 5 shows a probe fixture or apparatus 300 having a first housing 302 that is generally in the shape of an inverted “U” and that includes a body 304 and a pair of spaced-apart protruding feet 306 and 308. One of the feet 306 is generally wedge-shaped with opposed front and back faces 310 and 312. (“Wedge-shaped” means trapezoidal, and/or presenting two opposed, non-parallel surfaces/faces.) A recess 314 is formed in the front face 310. Biasing means or device such as the illustrated elastic block 316 are positioned in the recess 314. An eddy current probe 318 is disposed in the recess 314, encapsulated by the elastic block 316. It will be understood that the probe 318 may be constructed like any of the example probes 14, 114, or 214 described above. A spring element 320 such as the illustrated coil spring or an elastic member biases the probe 318 outwards. Optionally, small resilient pads or bumpers 322 may be provided on the bottom edges or surfaces of the feet 306 and 308. A multi-conductor cable or other electrical cabling 324 provides a connection to external electrical equipment, such as the signal processing equipment described above and/or to a switch 326 which may be used to trigger various data operations. The probe fixture 300 is used by placing the feet 306 and 308 between teeth of the gear G. The action of the elastic block 316 (biasing device) forces the foot 306 into a position of firm contact with the flank F of the gear teeth. Simultaneously, the spring element 320 urges the probe 318 into firm contact with the flank F. This places the probe 318 in a known position relative to the gear G and in solid contact therewith.

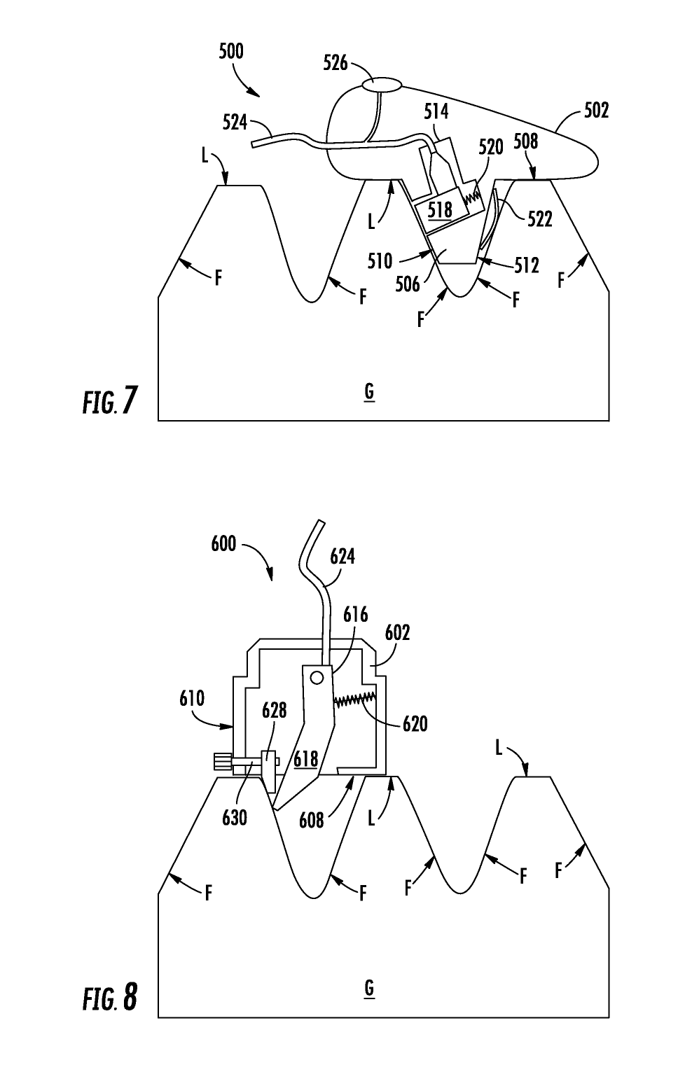

FIG. 6 shows another probe fixture or apparatus 400 including a first housing 402 having a body 404 and a wedge-shaped foot 406 protruding from a lower surface 408 of the body 404. The foot 406 has opposed front and back faces 410 and 412. A recess 414 is formed in the body 404 and an eddy current probe 418 is disposed in the recess 414. The probe 418 may be constructed like any of the example probes 14, 114, or 214 described above. The probe 418 is able to translate along its longitudinal axis. A spring element 420 such as the illustrated coil spring or an elastic member biases the probe 418 outwards. A biasing means or device such as the illustrated elastic block 422 is positioned on the back face 412. A multi-conductor cable or other electrical cabling 424 provides a connection to external electrical equipment, such as the signal processing equipment described above and/or a switch 426 which may be used to trigger various data operations. The probe fixture 400 is used by placing the foot 406 between two teeth of the gear G. The action of the biasing means or device 422 forces the foot 406 into a position of firm contact with the flank F of the gear tooth. Simultaneously, the spring element 420 urges the probe 418 into firm contact with another portion of the gear G, such as the flank F of the adjacent gear tooth.

FIG. 7 shows another probe fixture or apparatus 500 including a first housing 502 that defines a reference surface 508. A wedge-shaped foot 506 with opposed front and back faces 510 and 512 protrudes from the reference surface 508. A recess 514 is formed in the foot 506 communicating with the front face 510, and a probe 518 is disposed in the recess 514. The probe 518 may be constructed like any of the example probes 14, 114, or 214 described above. The probe 518 is able to translate towards or away from the front face 510. A spring element 520 such as the illustrated coil spring or an elastic member biases the probe 518 towards the front face 510. Biasing means or device such as the illustrated leaf spring 522, a coil spring, or an elastic block is positioned on the back face 512. A multi-conductor cable or other electrical cabling 524 provides a connection to external electrical equipment, such as the signal processing equipment described above and/or a switch 526 which may be used to trigger various data operations. The probe fixture 500 is used by placing the reference surface 508 against a portion of the gear G, such as the top lands L. The foot 506 protrudes between two adjacent gear teeth. The action of the biasing means or device 522 forces the foot 506 into a position of firm contact with the flanks F of the gear teeth. Simultaneously, the spring element 520 urges the probe 518 into firm contact with the flank F.

FIG. 8 shows yet another probe fixture or apparatus 600 including a first housing 602 that defines a reference surface 608. A probe 618 similar in construction to the probes 14, 114, or 214 described above protrudes from the reference surface 608. The probe 618 is mounted on an axis 616 so that it can pivot towards or away from a forward end 610 of the housing 602. A spring element 620 such as the illustrated coil spring or an elastic member biases the probe 618 towards the forward end 610. A stop 628 protrudes from the reference surface 608 between the forward end 610 and the probe 618. A means or device such as the illustrated threaded rod 630 is provided for adjusting the longitudinal position of the stop 628. A multi-conductor cable or other electrical cabling 624 provides a connection to external electrical equipment, such as the signal processing equipment described above. The probe fixture 600 is used by placing the reference surface 608 against a portion of the gear G, such as the top lands L of the gear teeth. The fixture 600 is then translated until the stop 628 makes firm contact with another portion of the gear G, such as the illustrated flank F of the gear tooth.

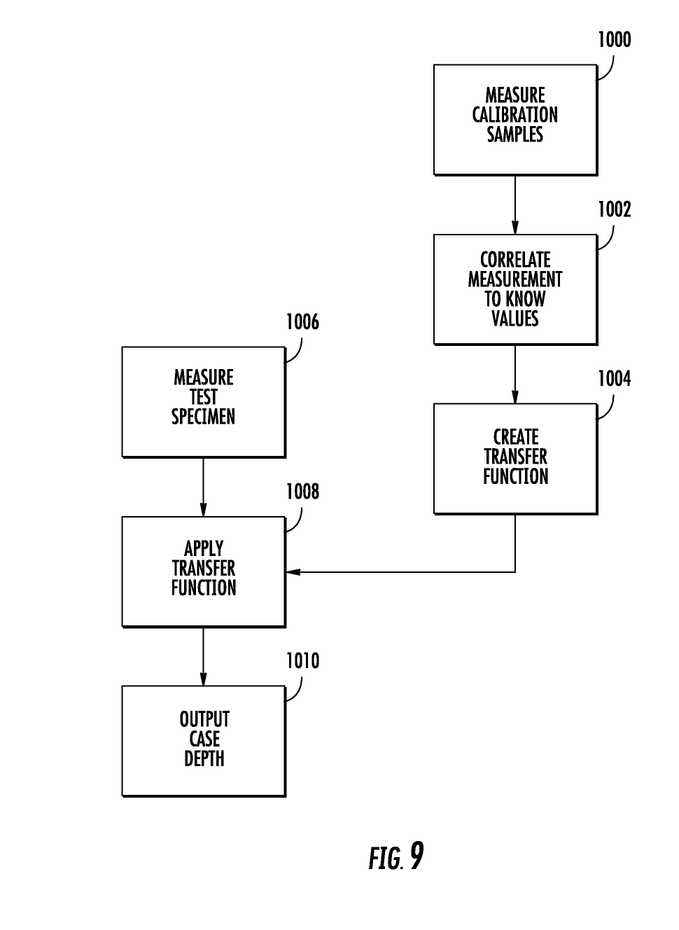

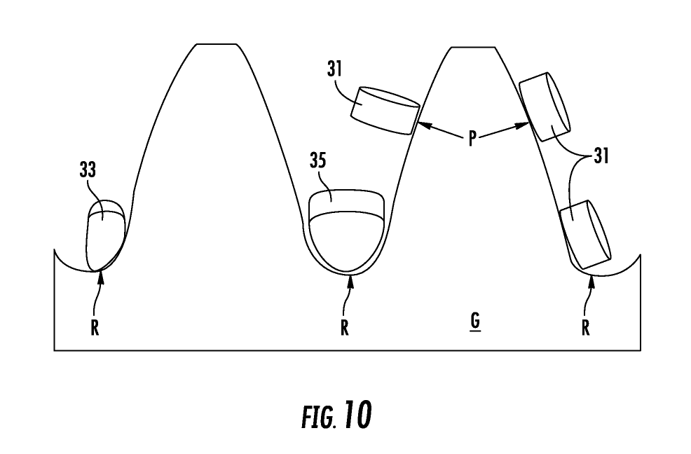

FIG. 9 is a block diagram showing an eddy current case depth measurement method or process, which may be carried out using the apparatus described above, according to an embodiment of the invention. As a first step, a set of calibration samples having a known case depth is provided. The calibration samples are made of the same alloy as the test specimens to be inspected, have the same local geometry as the test specimens, and are heat treated to the same condition. For example, if a steel gear or similar component is to be tested, several steel calibration samples each representative of the profile of a single tooth or several teeth of the gear may be used. An example of a portion of a gear is shown in FIG. 5. The case depth of the calibration samples may be determined by destructive methods such as indenter tests or by sectioning and micro-hardness mapping. At block 1000, the probe 14 is placed on each of the calibration samples, an eddy current is generated, and a measured eddy current is recorded.

The basic process of obtaining a “measured eddy current” using the inspection system 10 is the same both for calibration samples and for actual test specimens, and will described in general. Initially, a digital signal generated by the computer 12 and processed through the D/A converter 18 and power amplifier 20 (see FIG. 1) is used to excite drive coils 32 of the eddy current probe (see FIG. 2), while the probe 14 is contacting or adjacent to a location on a surface of a metal object (e.g., the calibration sample or the test specimen). As a result, an eddy current is generated in the metal object. Depending on the particular application, the induced current may be continuous or it may be an essentially short-duration pulse of electrical current. (In an embodiment, “short-duration” means an on portion of the pulse (current>0) is up to and including 300 ms in duration; in another embodiment, “short-duration” means the total period of each pulse (current=0 and current>0) is no more than 300 ms in duration.) The signal generation may be triggered by operation of the switches 326, 426, 526, or 626 described above.

In an embodiment, the inspection system 10 is operated in a “burst” mode. In this mode, the drive coils 32 of the probe 14 are driven only for a short time window when taking a measurement. The output of the probe 14 is sensitive to temperature, and drive current passing through the drive coil 32 heats the probe 14. Limiting the time of operation reduces the heat generated in the probe 14, thus limiting the probe's temperature rise. For example, the “on” time may be limited to a significant temperature rise of about 0.5° C. (0.9° F.) or less. This burst mode operation avoids the typical long time required for a probe 14 to warm up and achieve a stable temperature when operated continuously. The driven or “on” time is selected based on the signal frequency to give a few cycles of excitation. The latency time until the next burst may be 10 times that of the “on” time as an example.

The sense coils 34 sense the eddy current as a voltage. For example, an eddy current might produce a signal ranging from +500 mV to −500 mV in the sense coils 34 for a particular test specimen. It is noted that a sense coil 34 that measures eddy current may produce either a voltage or a current indicative of the eddy current. Therefore, “a measured eddy current,” as used herein, includes any measured representation of the eddy current, whether the representation is in the form of a voltage, a current, or a digitized value. The measured eddy current signal is processed through the signal preconditioner 22 and A/D converter 24 (see FIG. 1) and subsequently passed to the computer 12 as a digitized signal representative of the measured eddy current. The digitized value may be stored in volatile or nonvolatile memory of the computer 12 for further processing.

Referring back to FIG. 9, at block 1002, once the calibration samples have been measured, the measured eddy currents are correlated to the known case depth values. The correlation is embodied in a calibration curve that is generated using a stored program in the computer 12, showing the relationship between output and sample case depth. The curve can take the form of a stored table of eddy current measurements and corresponding case depth values (i.e., a “lookup table”) or graphical representation in memory of the computer 12. The substance of the calibration curve can use a piecewise linear algorithm, linear fitting, or any other known technique suitable for characterizing the correspondence between the measurements and the known case depth values. The result is a transfer function of the type y=ƒ(x) (see block 1004).

Once the transfer function is created and stored, the probe 14 is placed on a test specimen (for example a gear G) and measured eddy current values are generated as described above and provided to the computer 12 (block 1006). The measured eddy current values are then fed to the transfer function (block 1008) and a case depth of the unknown test specimen T is calculated or otherwise determined using the transfer function. Case depth output (block 1010) can be displayed in real time and/or saved in a data file and/or printed. In practice, a fixture such as the fixtures 300, 400, 500, or 600 described above may be used to take multiple local case depth measurements at selected spaced-apart points on a component and to compare the measurements against the component's manufacturing specifications, thereby verifying the quality of the case-hardening process.

In addition to determining the case depth as described above, embodiments of the invention described above may be used to obtain a hardness profile (that is, a graph or other representation of the hardness measurement versus the depth from the surface S of a test specimen T). Portions of a test specimen T having different hardness will react differently depending upon the frequency of the current driving the drive coils 32. By testing a set of calibration samples each having a known hardness, using a range of drive current frequencies, a calibration curve and transfer function for hardness can be developed as described above for the case depth calibration curve. The calibration curve may be embodied in a stored lookup table. Test specimens T may then be tested using a range of drive current frequencies to generate eddy currents in the object having a plurality of selected frequencies and to generated a measured eddy current. The transfer functions are then applied to the measured eddy currents to determine both case depth and hardness at each depth. This multi-frequency testing may be done by performing sequential measurements on the same test specimen T using different frequencies, or by simultaneously applying multiple drive frequencies and sensing the response for each frequency.

An embodiment relates to an apparatus for determining a case depth at a location in a surface of a metal object. The apparatus includes a first housing having a body with at least one foot protruding therefrom, the at least one foot configured to engage the flanks so as to retain the first housing in a stable orientation relative to the metal object. “Stable” orientation is defined as the at least one foot engaging the flanks at three or more non-colinear points (i.e., not all the points are in the same line) and/or at two or more non-colinear lines.

The foregoing has described embodiments of apparatus and methods for eddy current inspection of components having a complex geometric shape. While specific embodiments of the present invention have been described, it will be apparent to those skilled in the art that various modifications thereto can be made without departing from the spirit and scope of the invention. Accordingly, the foregoing description of the embodiments of the invention and the best mode for practicing the invention are provided for the purpose of illustration only and not for the purpose of limitation, the invention being defined by the claims.

In the appended claims, the terms “including” and “in which” are used as the plain-English equivalents of the respective terms “comprising” and “wherein.” Moreover, in the following claims, the terms “first,” “second,” “third,” “upper,” “lower,” “bottom,” “top,” “up,” “down,” etc. are used merely as labels, and are not intended to impose numerical or positional requirements on their objects. As used herein, an element or step recited in the singular and proceeded with the word “a” or “an” should be understood as not excluding plural of said elements or steps, unless such exclusion is explicitly stated. Furthermore, references to “one embodiment” of the invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

What is claimed is:

1. A method for determining a case depth of a surface of a metal object, comprising:
(a) placing an eddy current probe at a location on the surface;
(b) using the eddy current probe, generating a time-varying eddy current in the object;
(c) using the eddy current probe, measuring the eddy current and providing a signal representative of the measured eddy current to a computer;
(d) using the computer, comparing the measured eddy current to a correlation of measured eddy currents to known case depths; and
(e) determining the case depth at the location of the probe based on the correlation.

2. The method of claim 1 wherein steps (a) through (e) are carried out for a predetermined amount of time insufficient to cause significant temperature rise of the eddy current probe, followed by stopping generation of the eddy current and waiting for a predetermined latency time before repeating steps (a) through (e).

3. The method of claim 1 further comprising repeating steps (a) through (e) at a plurality of spaced-apart locations across the surface of the metal object.

4. The method of claim 1 wherein the eddy current is generated as one or more short-duration pulses.

5. The method of claim 1 wherein the correlation is a transfer function derived from measured eddy currents obtained from calibration samples having known case depths.

6. The method of claim 1 wherein the correlation is a lookup table derived from measured eddy currents obtained from calibration samples having known case depths.

7. The method of claim 1 wherein the eddy current probe is carried by a fixture having a first surface adapted to bear against the metal object and a spring element arranged to urge a tip of the probe against the surface.

8. The method of claim 1 further comprising:
(f) using the eddy current probe, generating eddy currents in the object having a plurality of selected frequencies;
(g) using the eddy current probe, outputting a measured eddy current for each frequency and providing a signal representative of the measured eddy current for each frequency to the computer; and
(h) using the computer, comparing the measured eddy currents for each frequency to a hardness correlation of measured eddy currents of the selected frequencies to known material hardnesses; and
(i) determining the material hardness at the location of the probe based on the hardness correlation.

9. The method of claim 8 wherein steps (f) through (i) are carried out sequentially for each of the selected frequencies.

10. The method of claim 8 wherein steps (f) through (i) are carried out simultaneously for all of the selected frequencies.

11. The method of claim 8 wherein the hardness correlation is a transfer function derived from measured eddy currents obtained from calibration samples having known material hardness.

12. The method of claim 8 wherein the hardness correlation is a lookup table derived from measured eddy currents obtained from calibration samples having known material hardness.

13. An apparatus for determining a case depth at a location in a surface of a metal object, comprising:
an eddy current probe including at least one drive coil and at least one sense coil;
a computer; and
signal processing equipment operably connected to the computer and the eddy current probe, the signal processing equipment operable to drive the at least one drive coil in response to the computer and to generate output signals representative of measured eddy currents produced by the at least one sense coil;
wherein the computer is programmed to:
(i) command the signal processing equipment to generate a time-varying eddy current in the metal object using the at least one drive coil;
(ii) receive signals representative of a measured time-varying eddy current from the signal processing equipment;
(iii) compare the measured time-varying eddy current to a correlation of measured eddy currents to known case depths; and
(iv) determine the case depth at the location of the probe based on the correlation.

14. The apparatus of claim 13 wherein the computer is programmed to carry out steps (i) through (iv) for a predetermined amount of time insufficient to cause significant temperature rise of the eddy current probe, followed by stopping generation of the eddy current and waiting for a predetermined latency time before repeating steps (i) through (iv).

15. The apparatus of claim 13 wherein the computer is programmed to generate the eddy current as one or more short-duration pulses.

16. The apparatus of claim 13 wherein the correlation is a transfer function derived from measured eddy currents obtained from calibration samples having known case depths.

17. The apparatus of claim 13 wherein the correlation is a lookup table derived from measured eddy currents obtained from calibration samples having known case depths.

18. The apparatus of claim 13 wherein the eddy current probe is carried by a fixture having a first surface adapted to bear against the metal object and a spring element arranged to urge a tip of the probe against the surface.

19. An apparatus for determining a case depth at a location in a surface of a metal object having a shape which comprises a plurality of teeth, each tooth having a land adjoined by spaced-apart flanks, wherein the flanks define recessed roots between adjacent lands, the apparatus comprising:
a first housing including a body with at least one foot protruding therefrom, the at least one foot configured to engage the flanks so as to retain the first housing in an orientation relative to the metal object;
an eddy current probe carried by the first housing, the probe comprising: a probe housing enclosing at least one drive coil and at least one sense coil, and electrical cabling connected to the at least one drive coil and the at least one sense coil for electrical connection to external electrical equipment; and
a spring element disposed between the first housing and the eddy current probe and arranged to urge the eddy current probe away from the first housing.

20. The apparatus of claim 19 wherein the at least one foot is wedge-shaped.

21. The apparatus of claim 19 further comprising a resilient biasing device carried by and protruding from one of the at least one foot.

22. The apparatus of claim 19 comprising a pair of spaced-apart feet protruding from the body, wherein the eddy current probe is carried on one of the pair of spaced-apart feet.
